(19) United States
(12) Patent Application Publication
(10) Pub. No.: US 2013/0037931 A1
(43) Pub. Date: Feb. 14, 2013

(54) SEMICONDUCTOR PACKAGE WITH A HEAT SPREADER AND METHOD OF MAKING

(71) Applicant: LEO M. HIGGINS, III, Austin, TX (US)

(72) Inventor: LEO M. HIGGINS, III, Austin, TX (US)

(21) Appl. No.: 13/205,228

(22) Filed: Aug. 8, 2011

(51) Int. Cl. H01L 21/56; H01L 23/34

(52) U.S. Cl. 257/712; 438/127; 257/E21.502; 257/E23.08

(57) ABSTRACT

An apparatus and method of forming a semiconductor package includes having and applying, respectively, a thermal interface material on a semiconductor die. The semiconductor die is included on a die assembly. The semiconductor die is installed in a heat spreader. The heat spreader is at least partially filled with mold compound and the semiconductor die is at least partially immersed in the mold compound once the die assembly is mounted on the heat spreader. The mold compound is then cured.

### FIELD

This disclosure relates generally to molded packages for semiconductor devices, and more specifically, to molded packages for semiconductor devices with heat spreaders.

### RELATED ART

Heat dissipation in semiconductor devices continues to be an issue. Especially as the number of transistors continues to increase, heat dissipation demands also increase. The typical solution is to include a heat spreader in the packaging process. Cost of course is an issue as well so that heat dissipation techniques are preferably cost effective. Also the size of the package is an issue. Generally the smaller the size the better. Small size, however, can make heat dissipation more difficult because it can limit the area of the heat spreader, although it may be possible for the heat spreader to extend beyond the perimeter of the packaged device body in some configurations. Further, the molding process itself can create issues. For example, in the case of wire bonded semiconductor devices, the wires can touch each other during the molding process due to what is commonly called bond wire sweep.

Thus, there is a need for making a molded package for a semiconductor device with a heat spreader that improves upon one or more of the issues raised above.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 is a cross section of a semiconductor device that is wire bonded to a substrate;

FIG. 2 is the semiconductor device of FIG. 1 with further processing;

FIG. 3 is a cross section of a heat spreader aligned to a mold;

FIG. 4 is a cross section of the heater spreader on the mold.

FIG. 5 is a cross section of the heater spreader held in the mold by vacuum;

FIG. 6, is a cross section of the semiconductor device of FIG. 2 aligned to the heat spreader and mold with the mold containing liquid mold compound;

FIG. 7 is a cross section of the semiconductor device of FIG. 2 in the liquid mold compound;

FIG. 8 is a cross section of the semiconductor of FIG. after the liquid mold compound has become solid and the semiconductor device with the heat spreader has been removed from the mold;

FIG. 9 is a bottom view of an alternative heat spreader,

FIG. 10 is a cross section of the heat spreader of FIG. 9;

FIGS. 11-14 are bottom views of further alternative heat spreaders; and

FIG. 15 is a cross section of the further alternative heat spreader of FIG. 14.

### DETAILED DESCRIPTION

In one aspect, a heat spreader is placed into a mold. Liquid mold compound is formed over the heat spreader. A thermal interface is placed on the semiconductor die that is mounted on a substrate. The thermal interface has relatively high thermal conductivity and relatively low modulus of elasticity in comparison to the hardened and cured mold compound. The semiconductor device is placed into the liquid mold compound to contact the thermal interface with the heat spreader. The mold compound is cooled and solidified. After solidifying, the semiconductor device is removed from the mold with the heat spreader attached. The result is an efficient molding process with a resulting high heat dissipation characteristic. This is better understood with reference to the drawings and the following written description.

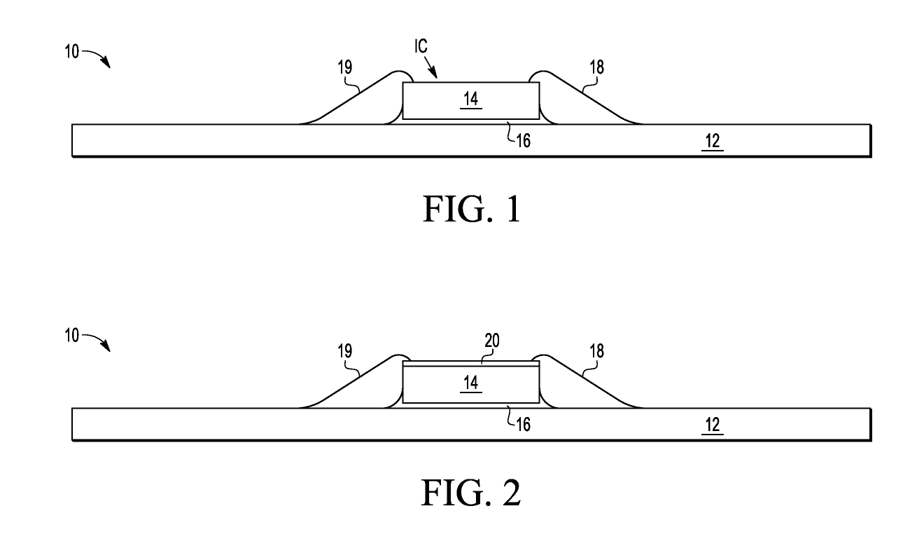

Shown in FIG. 1 is a semiconductor device structure 10, which may also be called a die assembly, having a substrate 12, a semiconductor die 14 attached to the substrate with a die attach adhesive 16, and wire bonds, such as wire bonds 18 and 19, connected between semiconductor die 14 and substrate 12. There may be may be hundreds of wire bonds in close proximity to each other connected between semiconductor die 14 and substrate 12. Substrate 12 is designed to receive solder balls for connecting to a printed circuit board and also to receive an overmolding of semiconductor die 14 and the wire bonds such as wire bonds 18 and 19. While FIG. 1 shows one die 14 mounted on substrate 12, it is understood that substrate 12 could also be an array of multiple substrate sites equivalent to substrate 12, and that multiple die 14 could be assembled on this array of substrates, and the individual assembled and encapsulated units could be cut from the supporting array after assembly and solder ball attach is completed.

Shown in FIG. 2 is semiconductor device structure 10 after applying a thermal interface 20 on semiconductor die 14. Thermal interface 20 has a thermal conductivity higher than that of a mold compound that will be used for the overmolding of semiconductor die 14. Additionally, thermal interface 20 has a lower modulus of elasticity than does the mold compound. Thermal interface 20 is an electrical insulator. Thermal interface 20 may be a high temperature fill grease, a low modulus silicon elastomer, a low modulus epoxy, or other suitable material. Each of these would further include a high thermal conductivity particulate filler such as zinc oxide, aluminum oxide, boron nitride, and aluminum nitride. Other materials may be found to be effective as well.

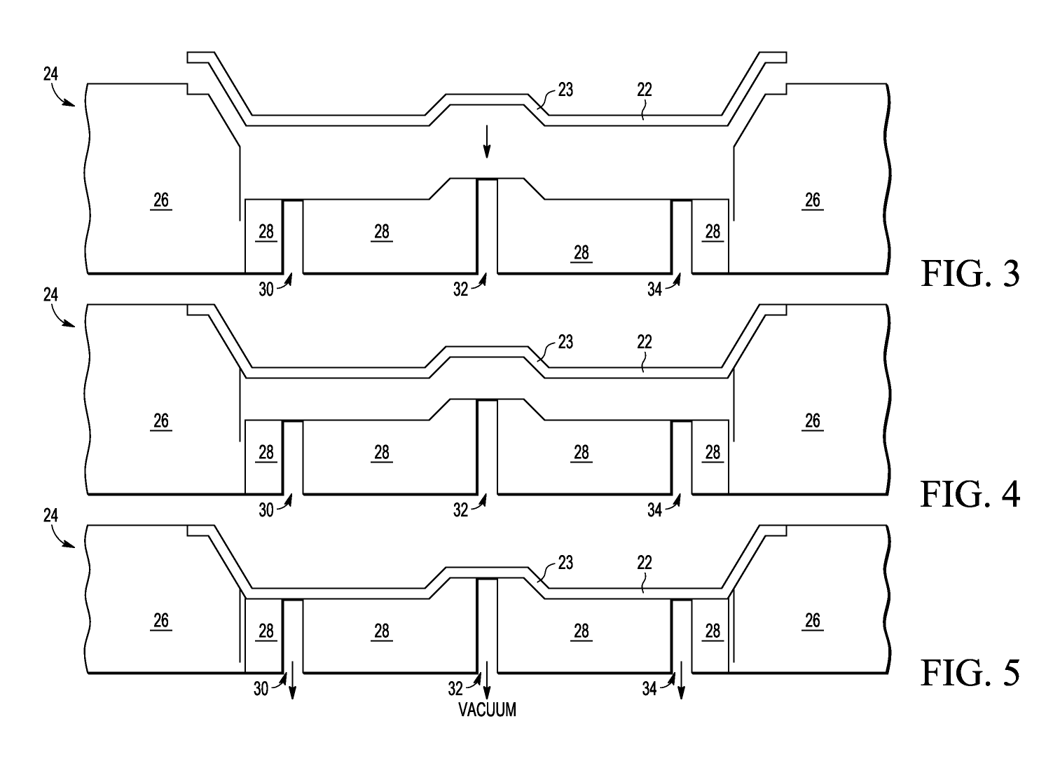

Shown in FIG. 3 is a heat spreader 22 having pedestal 23 as portion of heat spreader 22 and a mold 24. Mold 24 includes a portion 26 that provides support for a movable portion 28. Portion 26 may also move up and down in the operation of a given mold press. Movable portion 28 has openings 30, 32, and 34 for applying a vacuum to heat spreader 22. A top surface of movable portion 28 in FIG. 3 has a similar shape as that of heat spreader 22. Heat spreader 22 may be copper. It may also be aluminum or other appropriate highly thermally conductive material. Apart from forming the heat spreader itself, the process from this point forward is performed in a vacuum.

Shown in FIG. 4 is heat spreader 22 placed on mold 24 and in contact with portion 26.

Shown in FIG. 5 is movable portion 28 in contact with heat spreader 22. Movable portion 28 holds heat spreader 22 in place with vacuum applied through openings 30, 32, and 34. In this case, a corresponding shape to pedestal 23 is present in movable portion 28 to support pedestal 23 so that pedestal 23 will retain its shape and stay properly positioned in mold 24. It may not be necessary for the corresponding shape to be present if the rigidity and strength of heat spreader is sufficient without the corresponding shape being present and if the interior walls of mold portion 26 are sufficient to align heat spreader 22 in mold 24. The vacuum is preferably sufficient to hold heat spreader 22 in place and prevent mold compound 46 from penetrating between mold 24 and heat spreader 22.

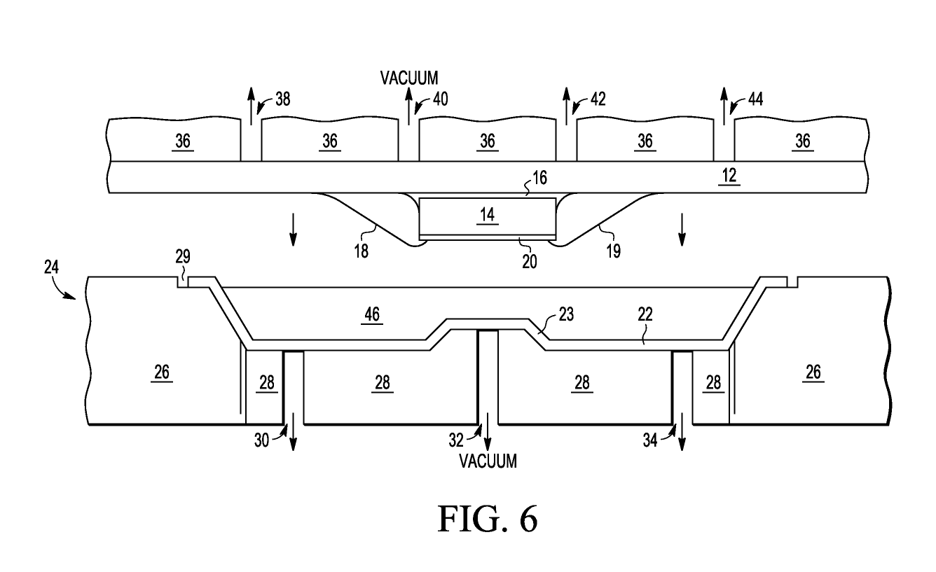

Shown in FIG. 6 is mold 24 with a mold compound 46 over heat spreader 22 and to a depth sufficient for overmolding of semiconductor die 14. Semiconductor device structure 10 of FIG. 2 is held in position by a vacuum handler 36 having openings 38, 40, 42, and 44 for applying the vacuum to substrate 12. Vacuum handler 36 aligns semiconductor die 14 to pedestal 23. Vacuum handler 36 may be part of the overall mold tool that also includes mold 24 and may only move in the vertical direction. Mold compound 46 may be disposed in liquid form into heat spreader 22 as one approach. Another approach is to place mold compound powder over heat spreader 22 while held in heated mold 24 to obtain liquid mold compound 46. In either case, the amount of mold compound 46 is determined to fill heat spreader 22 to minimize overflowing heat spreader 22 with mold compound 46 when semiconductor die 14 is immersed. The heat spreader 22 thus may not be completely filled but may be partially filled with mold compound 46. A gap 29 is around the edge of heat spreader 22 is used to accommodate overflow of mold compound 46. Gap 29 is a segment of a larger recessed region around the edge of mold portion 26. The outer edge of heat spreader 22 is seated in an inner segment of the larger recessed region. The depth of the larger recessed region may be equal to the thickness of the outer edge of the heat spreader. The depth of the larger recessed region may also be greater than the thickness of the edge of heat spreader 22, which would result in a thicker layer of mold compound 46 between the outer edge of heat spreader 22 and the surface of substrate 12. The depth of the larger recessed region may also exceed the thickness of the edge of heat spreader 22 in the configuration shown in FIG. 4, where the design feature of gap 29 is not present.

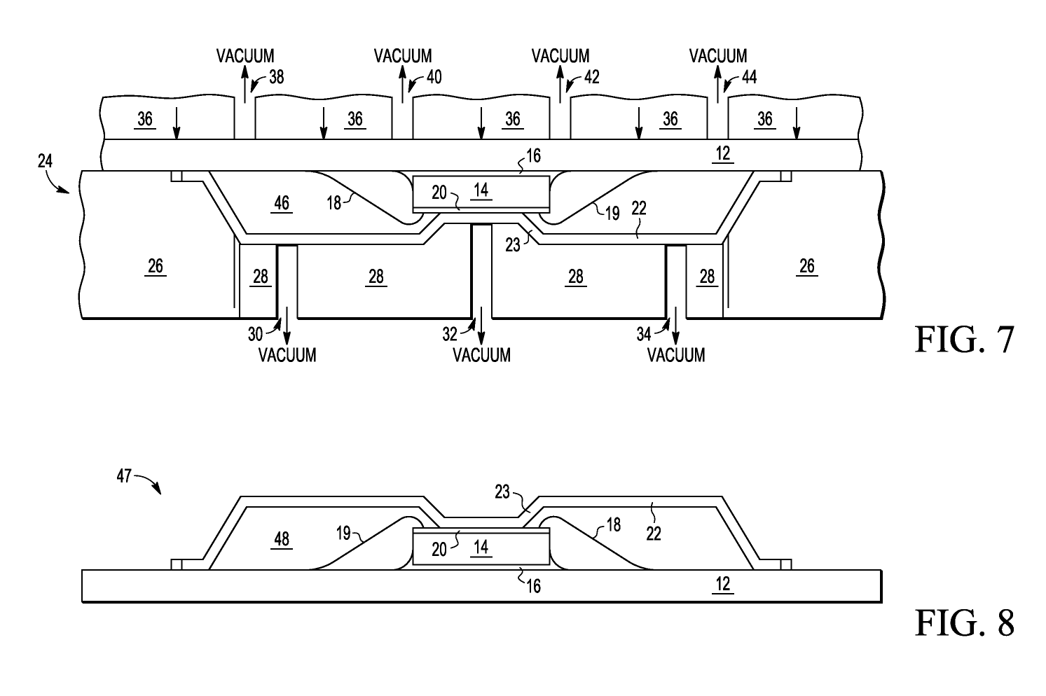

Shown in FIG. 7 is semiconductor die 14 submerged in mold compound 46 and semiconductor die 14 in contact with thermal interface 20. Mold compound 46 also comes in contact with substrate 12 as well as a portion of semiconductor die 14 and die attach adhesive 16. The submersion of semiconductor die in mold compound 46 is done sufficiently slowly to avoid bond wire sweep that is sufficient to short two bond wires together. The rate of submersion allows for control of bond wire sweep. Unlike transfer molding where mold compound is injected at fairly high velocity into a mold, this compression molding operation immerses the bond wires and semiconductor die 14 into mold compound slowly. The submersion may take 0.5 to 5 seconds or more if needed for full immersion resulting in very little bond wire deformation and very little wire bond sweep. The speed of submersion should take into account density of wire bonds, viscosity of the mold compound, and stiffness of the wire bonds. Additionally, semiconductor die 14 is contacted, under pressure, to pedestal 23. Thermal coating 20 may be deformed by pedestal 23 and effectively absorb stress from as well as providing good contact to pedestal 23.

Shown in FIG. 8 is a semiconductor package 47 having semiconductor die after cooling and solidification of mold compound 46 to form solid mold compound 48 with the result that semiconductor die 14 is in close thermal contact with heat spreader 22 through thermal interface 20. Thus, semiconductor package 47 is formed by curing liquid mold compound 46 of FIG. 7. Heat spreader 22 has substantially the same surface area as mold compound 48 thus taking advantage of the available surface area to dissipate heat. It may be noted that mold compound 46 that overflows the lid and into gap 29 is attached to heat spreader 22 at its perimeter as shown in FIG. 8.

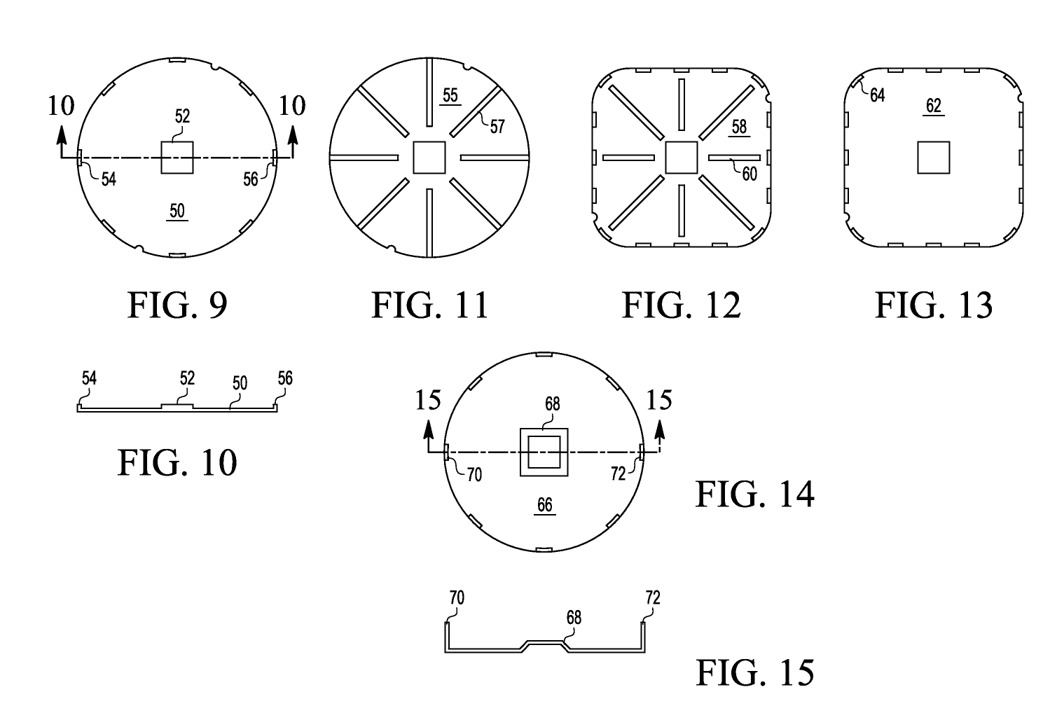

Shown in FIG. 9 is a bottom view of a heat spreader 50 that may replace heat spreader 22. Heat spreader 50 has a pedestal 52, and a plurality of raised features along the perimeter such as a raised feature 54, and a raised feature 56. The raised features are for providing additional adhesion between the mold compound and the heat spreader.

Shown in FIG. 10 is a cross section 10-10 as shown in FIG. 9 of heat spreader 50 showing pedestal 52 and raised features 54 and 56. Features 54 and 56 are relatively small and do not extend along the sides of the semiconductor die. Being relatively small, they can be preferably formed by etching and may also be formed by coining or stamping.

Shown in FIG. 11 is a bottom view of a heat spreader 55 with raised features such as raised feature 57 to provide additional adhesion between the mold compound and the heat spreader, to increase radial heat spreading and to increase rigidity of heat spreader 54. The pedestal is the same as for heat spreader 50. Also the features are relatively small and can be etched and may also be formed by coining or stamping.

Shown in FIG. 12 is a bottom view of a heat spreader 58 with raised features such as raised feature 60 to provide additional adhesion between the mold compound and the heat spreader, to increase radial heat spreading and to increase rigidity of heat spreader 58. The pedestal is the same as for heat spreader 50. Also the features are relatively small and can be etched and may also be formed by coining or stamping.

Shown in FIG. 13 is a bottom view of a heat spreader 62 with raised features such as raised feature 64. The pedestal is the same as for heat spreader 50. Also the features are relatively small and can be etched and may also be formed by coining or stamping.

Shown in FIG. 14 is a bottom view of a heat spreader 66 with raised features 70 and 72 along the perimeter and pedestal 68

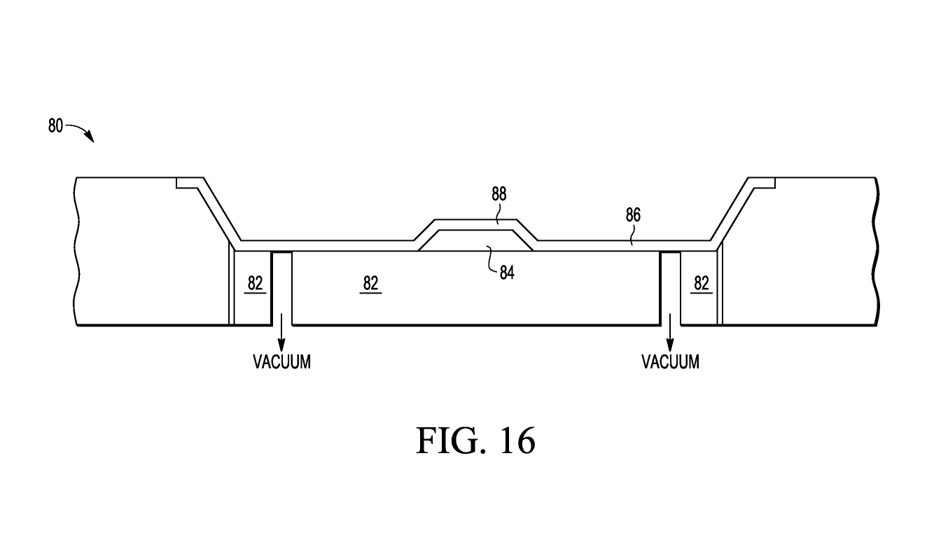

Shown in FIG. 15 is a cross section 15-15 as shown in FIG. 14 showing that the raised features, such as raised features 70 and 72, are relatively long and would extend to the substrate of the semiconductor device structure similar to that shown in FIG. 8 for heat spreader 22 where heat spreader 22 has angled sides for pedestal 23 as well as for the sides that contact the semiconductor substrate. As shown for heat spreader 66, the raised features such as features 70 and 72 are vertical rather than angled. Pedestal 68 is angled as is pedestal 23 of heat spreader 22.

Shown in FIG. 16 is a mold 80 and heat spreader 86 with a pedestal 88. Mold 80 has a movable member 82 that is an alternative to movable portion 28 as shown in FIG. 5. Mold 80 does not have the feature that conforms to the pedestal of the heat spreader. Location 84 under pedestal 88 would be where the feature conforming to pedestal 88 would be located, but this feature is not present on movable member 82. In this case the rigidity and strength of heat spreader 86 is relied upon to be sufficient. This approach is beneficial because other heat spreaders may be easily substituted for others since movable member 82 does not have to conform to the shape of the pedestal of the heat spreader. Processing continues as shown and described in FIGS. 6-8 to form a semiconductor package.

Thus, a semiconductor package is formed efficiently and in a manner which results in a heat spreader that provides efficient heat spreading by correlating the area of the heat spreader to that of the full surface of the mold compound or the top surface of the mold compound formed around the semiconductor die.

By now it should be appreciated that there has been provided a method of forming a semiconductor device. The method includes filling a thermally conductive heat spreader with a mold compound. The method further includes if the mold compound is not already in a liquid state, processing the mold compound until the mold compound is in the liquid state. The method further includes lowering a die assembly into the mold compound to immerse wire bonds and a semiconductor die in the mold compound The method further includes curing the mold compound to form the semiconductor package. The method may further comprise applying a layer of thermal interface material to a junction surface of the die before immersing the die assembly in the mold compound. The method may further comprise determining an amount of the mold compound to use to fill the thermally conductive heat spreader to minimize overflowing the thermally conductive heat spreader with the mold compound when the semiconductor die is immersed. The method may further comprise placing the conductive heat spreader in a mold cavity. The method may further comprise retaining the conductive heat spreader in the mold cavity using a vacuum force. The method may further comprise lowering the die assembly at a rate that avoids deforming the wire bonds. The method may have a further characterization by which the thermal interface material has a characteristic comprising one of a group consisting of: being more thermally conductive than the mold compound and having a lower modulus of elasticity than the mold compound. The method may have a further characterization by which the mold cavity includes a gap around the edge of the heat spreader to accommodate overflow mold compound.

Also described is a method of forming a semiconductor package including applying a thermal interface material on a semiconductor die, wherein the semiconductor die is included in a die assembly. The method further includes installing the semiconductor die in a heat spreader, wherein the heat spreader is at least partially filled with a mold compound and the semiconductor die is at least partially immersed in the mold compound once the die assembly is mounted on the conductive heat spreader. The method further includes curing the mold compound. The method may have a further characterization by which the heat spreader includes a pedestal adjacent the semiconductor die and the thermal interface material is between the semiconductor die and the pedestal. The method may further include determining an amount of the mold compound to use to fill the heat spreader to minimize overflowing the heat spreader with the mold compound when the die assembly is immersed. The method may further include placing the heat spreader in a mold cavity and retaining the heat spreader in the mold cavity using a vacuum force. The method may further include determining a speed for lowering the die assembly into the mold compound based on a characteristic comprising one of a group consisting of: a density of wire bonds between the semiconductor die and a substrate, a viscosity of the mold compound, and a stiffness of the wire bonds. The method may further include retaining the die assembly is a compression tool using a vacuum force and applying pressure to the die assembly with the compression tool once the die assembly is immersed in the mold compound. The method may further include if the mold compound is not already in a liquid state, processing the mold compound until the mold compound is in the liquid state. The method may further include the thermal interface material has a characteristic comprising one of a group consisting of: being more thermally conductive than the mold compound and having a lower modulus of elasticity than the mold compound. The method may have a further characterization by which the method is performed in a vacuum environment.

Described also is a semiconductor package that has a assembly including a semiconductor die. The semiconductor package further includes a thermally conductive heat spreader including a pedestal adjacent the semiconductor die. The semiconductor package further includes a thermal interface material in a gap between the semiconductor die and the pedestal. The semiconductor package further includes a mold compound between the die assembly and the heat spreader. The semiconductor package may have a further characterization by which the thermally conductive heat spreader includes top and side portions that enclose the mold compound. The semiconductor package may have a further characterization by which the spreader includes one or more ribs having an effect comprising one of a group consisting of: stiffening the thermally conductive heat spreader, retaining the heat spreader in the mold compound, and increasing thermal conductivity of the heat spreader.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. For example, different heat spreaders may be used with different shapes than those disclosed. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. A method of forming a semiconductor package comprising:
filling a thermally conductive heat spreader with a mold compound;
if the mold compound is not already in a liquid state, processing the mold compound until the mold compound is in the liquid state;
lowering a die assembly into the mold compound to immerse wire bonds and a semiconductor die in the mold compound; and
curing the mold compound to form the semiconductor package.

2. The method of claim 1 further comprising:
applying a layer of thermal interface material to a junction surface of the die before immersing the die assembly in the mold compound.

3. The method of claim 1 further comprising:
determining an amount of the mold compound to use to fill the thermally conductive heat spreader to minimize overflowing the thermally conductive heat spreader with the mold compound when the semiconductor die is immersed.

4. The method of claim 1 further comprising:
placing the conductive heat spreader in a mold cavity.

5. The method of claim 4 further comprising:
retaining the conductive heat spreader in the mold cavity using a vacuum force.

6. The method of claim 1 further comprising:
lowering the die assembly at a rate that avoids deforming the wire bonds.

7. The method of claim 2 wherein
the thermal interface material has a characteristic comprising one of a group consisting of: being more thermally conductive than the mold compound and having a lower modulus of elasticity than the mold compound.

8. The method of claim 4, wherein the mold cavity includes a gap around the edge of the heat spreader to accommodate overflow mold compound.

9. A method of forming a semiconductor package comprising:
applying a thermal interface material on a semiconductor die, wherein the semiconductor die is included in a die assembly;
installing the semiconductor die in a heat spreader, wherein the heat spreader is at least partially filled with a mold compound and the semiconductor die is at least partially immersed in the mold compound once the die assembly is mounted on the conductive heat spreader; and
curing the mold compound.

10. The method of claim 9, wherein:
the heat spreader includes a pedestal adjacent the semiconductor die; and
the thermal interface material is between the semiconductor die and the pedestal.

11. The method of claim 9 further comprising:
determining an amount of the mold compound to use to fill the heat spreader to minimize overflowing the heat spreader with the mold compound when the die assembly is immersed.

12. The method of claim 9 further comprising:
placing the heat spreader in a mold cavity; and
retaining the heat spreader in the mold cavity using a vacuum force.

13. The method of claim 9 further comprising:
determining a speed for lowering the die assembly into the mold compound based on a characteristic comprising one of a group consisting of: a density of wire bonds between the semiconductor die and a substrate, a viscosity of the mold compound, and a stiffness of the wire bonds.

14. The method of claim 9 further comprising:
retaining the die assembly is a compression tool using a vacuum force; and
applying pressure to the die assembly with the compression tool once the die assembly is immersed in the mold compound.

15. The method of claim 9 further comprising:
if the mold compound is not already in a liquid state, processing the mold compound until the mold compound is in the liquid state.

16. The method of claim 9 further comprising:
the thermal interface material has a characteristic comprising one of a group consisting of: being more thermally conductive than the mold compound and having a lower modulus of elasticity than the mold compound.

17. The method of claim 9 wherein the method is performed in a vacuum environment.

18. A semiconductor package comprising:
a die assembly including a semiconductor die;
a thermally conductive heat spreader including a pedestal adjacent the semiconductor die;
a thermal interface material in a gap between the semiconductor die and the pedestal; and
a mold compound between the die assembly and the heat spreader.

19. The semiconductor package of claim 18 wherein the thermally conductive heat spreader includes top and side portions that enclose the mold compound.

20. The semiconductor package of claim 18,
wherein the heat spreader includes one or more ribs having an effect comprising one of a group consisting of: stiffening the thermally conductive heat spreader, retaining the heat spreader in the mold compound, and increasing thermal conductivity of the heat spreader.
